(19) United States
(12) Patent Application Publication
(10) Pub. No.: US 2024/0195143 A1
(43) Pub. Date: Jun. 13, 2024

(54) LIGHT-EMITTING DEVICE AND LIDAR SYSTEM

(71) Applicant: ams-OSRAM Intemational GmbH, Regensburg (DE)

(72) Inventor: Norwin von Malm, Nittendorf (DE)

(21) Appl. No.: 18/552,291

(22) PCT Filed: Mar. 31, 2022
(86) PCT No.: PCT/EP2022/058571

§ 371 Date: Sep. 25, 2023

(30) Foreign Application Priority Data
Apr. 1, 2021 (DE) 102021108349.4

(51) Int. Cl. H01S 5/0225; G01S 7/481; H01S 5/042

(52) U.S. Cl. CPC H01S 5/0225; G01S 7/4814; H01S 5/04254

(57) ABSTRACT

In an embodiment a light-emitting device includes a housing body, a light-emitting semiconductor component in the housing body, the light-emitting component configured to emit light and an adaptive optical element in and/or on the housing body arranged downstream of the light-emitting semiconductor component in an optical path of the light, wherein the light-emitting device is a semiconductor package.

### CROSS-REFERENCE TO RELATED APPLICATIONS

This patent application is a national phase filing under section 371 of PCT/EP2022/058571, filed Mar. 31, 2022, which claims the priority of German patent application 102021108349.4, filed Apr. 1, 2021, each of which is incorporated herein by reference in its entirety.

### TECHNICAL FIELD

A light-emitting device is specified.

### BACKGROUND

The emission profile of light-emitting semiconductor packages, i.e. light sources that have one or more semiconductor light sources in a housing, can typically be influenced by lenses or dielectric filters. Usually, the selection of such optical components is made during the manufacture of the semiconductor package and cannot be changed during operation. To adjust the radiation characteristics, further external optical components are necessary in addition to the semiconductor package.

### SUMMARY

Embodiments provide a light-emitting device.

According to at least one embodiment, a light-emitting device comprises a light-emitting semiconductor component which is intended and configured to emit light during operation. Here and hereinafter, light refers to electromagnetic radiation in a wavelength range from infrared to ultraviolet radiation. For example, the light-emitting device can be intended and configured to emit light in a visible wavelength range. The emitted light can have one or more spectral components and can be, for example, monochromatic or mixed color.

According to an embodiment, the light-emitting semiconductor component has at least one light-emitting semiconductor chip or is embodied as at least one light-emitting semiconductor chip. In particular, this can mean that the light-emitting semiconductor component can have one or more light-emitting semiconductor chips. Even if a light-emitting semiconductor component formed as one light-emitting semiconductor chip is described purely by way of example in the following description, the following description also applies to a light-emitting device having a light-emitting semiconductor component which has a plurality of light-emitting semiconductor chips.

The light-emitting semiconductor component and in particular the at least one light-emitting semiconductor chip has in particular a semiconductor layer sequence with an active region for generating light. The active region can in particular have or be an active layer in which the light is generated during operation. Particularly preferably, the semiconductor layer sequence can be produced by means of an epitaxy process, for example by means of metal organic vapor phase epitaxy (MOVPE) or molecular beam epitaxy (MBE). The semiconductor layer sequence hereby has semiconductor layers stacked along an arrangement direction in a vertical direction given by the growth direction. Perpendicular to the vertical direction, the layers of the semiconductor layer sequence each have a main extension plane. Directions parallel to the main extension plane of the semiconductor layers are referred to in the following as lateral directions.

Purely by way of example, it is assumed that the light-emitting semiconductor component emits the light generated during operation along a main radiation direction which is perpendicular to the main extension plane of the semiconductor layers and thus in a vertical direction. However, the embodiments and features described below apply equally to a light-emitting semiconductor component in which the main radiation direction is formed along a different direction, for example along a direction parallel to the main extension plane of the semiconductor layers, i.e. along a lateral direction. An element arranged in the optical path of the light-emitting semiconductor component can preferably be arranged along the main radiation direction. However, other arrangement directions are also possible as long as they are such that, in operation, light can be emitted from the light-emitting semiconductor component onto said element arranged in the beam path.

The light-emitting semiconductor component has a light-outcoupling surface via which the light generated in the active region during operation is emitted. In particular, in the case of the main radiation direction perpendicular to the main extension plane of the semiconductor layers described above, the light-outcoupling surface can be a main surface of the semiconductor chip arranged perpendicular to the growth direction of the semiconductor layer sequence. Furthermore, the at least one semiconductor chip has a rear side opposite to the light-outcoupling surface, which can form a mounting surface with which the semiconductor chip can be arranged, for example, on a carrier such as the housing body described below. The light-outcoupling surface and the rear side are connected to each other via chip side surfaces, which delimit the semiconductor chip in the lateral direction. In addition to emitting light through the light-outcoupling surface, the light generated in the active layer during operation can also be emitted, for example, at least partially via the chip side surfaces. The proportion of light emitted in the direction of the element can be increased by a dielectric angle filter arranged on the light-outcoupling surface.

Furthermore, the at least one semiconductor chip can also have a side surface as a light-outcoupling surface so that the main radiation direction is directed parallel to the main extension plane. In this case, it can be advantageous if a side surface opposite the light-outcoupling surface forms a mounting surface of the semiconductor chip. Alternatively, a semiconductor chip emitting via a side surface can be mounted on a carrier with a main surface of the semiconductor layer sequence and, for example, emit light onto a reflector by means of which the light is preferably deflected in a vertical direction. Such a reflector can be formed as an additional component provided to the at least one semiconductor chip. Particularly preferably, such a reflector can also be formed, for example, as part of the semiconductor layer sequence of the at least one light-emitting semiconductor chip. In this case, the semiconductor layer sequence can have one or more trenches laterally adjacent to the active region. A side surface of such a trench bounding the active region can form a light-outcoupling surface, while a side surface of the trench opposite the light-outcoupling surface is oriented inclined, for example at an angle of 45°, with respect to the main extension plane of the semiconductor layers and forms a reflector surface. For this purpose, for example, a reflective coating for forming the reflector surface can be provided on the side surface of the trench.

The light-emitting semiconductor component can have a semiconductor layer sequence based on different semiconductor material systems depending on the light to be generated. For long-wave, infrared to red radiation, for example, a semiconductor layer sequence based on InₓGa_{y}Al_{1-x-y}As is suitable, for red to green radiation, for example, a semiconductor layer sequence based on InₓGa_{y}Al_{1-x-y}P is suitable, and for shorter-wave visible radiation, i.e. in particular for green to blue radiation, and/or for UV radiation, a semiconductor layer sequence based on InₓGa_{y}Al_{1-x-y}N is suitable, for example, where o≤x≤1 and o≤y≤1 applies in each case. For electrical contacting, the light-emitting semiconductor component, i.e., the at least one light-emitting semiconductor chip, can have contact layers by means of which an electric current can be injected into the semiconductor layer sequence for light generation during operation. In addition, further layers and elements can be present, for example a substrate on which the semiconductor layer sequence is deposited, passivation layers and/or mirror layers.

The light-emitting semiconductor component can, for example, comprise or be a light-emitting diode. The light-emitting diode (LED) can, for example, be embodied as a so-called volume emitter, as a thin-film semiconductor chip or as a flip chip, or can have at least one such chip. Furthermore, the light-emitting semiconductor component can comprise or be a laser diode. In particular, the light-emitting semiconductor component can be a surface-emitting laser diode, for example, a VCSEL (“vertical-cavity surface-emitting laser”) or a HCSEL (“horizontal-cavity surface-emitting laser”) or a PCSEL (“photonic-crystal surface-emitting laser”). In addition, the light-emitting semiconductor component can comprise or be a super luminescent diode (SLED).

Furthermore, in addition to the at least one semiconductor chip, the light-emitting semiconductor component can have a wavelength conversion material that can convert at least a portion of the light generated by the light-emitting semiconductor component in operation to light in a different wavelength range so that mixed color light can be generated, for example. Alternatively or additionally, mixed-color light can be generated by, for example, several different light-emitting semiconductor chips.

According to a further embodiment, the light-emitting device comprises a housing body. The housing body can, for example, have a cavity in which the light-emitting semiconductor component is arranged. Furthermore, the housing body can, for example, be formed as a carrier plate on which a ring forming a cavity can be arranged around the light-emitting semiconductor component. Furthermore, a cover plate can be used, in particular as described further below, which has a thickening at the edge with which the cover plate can be arranged on the carrier plate.

According to a further embodiment, the light-emitting device comprises an adaptive optical element which is arranged downstream of the light-emitting semiconductor component in the beam path of the light generated by the light-emitting semiconductor component during operation. In particular, the adaptive optical element is arranged in or on the housing body and is thus an integral part of the light-emitting device.

For example, the housing body can comprise a housing body material in the form of a plastic, in particular a thermoplastic or a thermoset, which can be produced, for example, by a molding process such as transfer molding, injection molding, compression molding, or a combination thereof. Accordingly, the housing body can comprise or be substantially formed thereby, for example, a plastic body in the form of a plastic housing. The plastic can, for example, comprise a silicone and/or an epoxy resin, or can comprise a silicone-epoxy hybrid material. Alternatively or additionally, the plastic can comprise, for example, polyphthalamide (PPA), polymethyl methacrylate (PMMA), polyacrylate, polycarbonate, and/or imide groups. Furthermore, the housing body can also comprise a ceramic material and thus, for example, comprise or be formed as a ceramic housing.

The housing body includes at least one electrical contact element for electrically contacting the elements arranged in and on the housing body, such as the light-emitting semiconductor component and the adaptive optical element. The at least one electrical contact element can, for example, include or be formed by one or more conductor paths, one or more electrical vias, one or more leadframes or leadframe portions, one or more electrode pads, and combinations thereof on one or more surfaces of the housing body material and/or embedded in the housing body material. In particular, the housing body can include a plurality of electrical contact elements as at least one electrical contact element. For example, the housing body can have one or more leadframes or leadframe portions with the housing body material molded thereon. For example, the housing body can form a so-called QFN (quad flat no leads) housing or at least a part thereof.

According to a further embodiment, the housing body has dimensions that are less than or equal to 5 cm or less than or equal to 2 cm or less than or equal to 1 cm or less than or equal to 0.5 cm or less than or equal to 0.3 cm. In other words, the light-emitting device is formed as a so-called semiconductor package. The light-emitting device can particularly preferably be a surface-mounted device, i.e. a so-called SMD (surface-mounted device), which can be mounted on a carrier such as a printed circuit board by soldering.

According to a further embodiment, the adaptive optical element has a plurality of structural elements. Particularly preferably, the adaptive optical element has a number of more than 7 structural elements in each direction parallel to the main extension plane. The structural elements have an extension size adapted to a wavelength of light generated by the light-emitting semiconductor component. This can mean, for example, that the structural elements have an extension size that is smaller than or equal to a wavelength of the light generated by the light-emitting semiconductor component. Accordingly, the adaptive optical element can have a sub-wavelength structure. Depending on the shape of the structural elements, the extension size can be, for example, a length, a width, a height, and/or a diameter, or an average of two or more of these dimensions.

The structural elements can be columnar, for example. This can mean that the structural elements can have, for example, a cylindrical shape or a frustoconical shape with a round or polygonal base.

Furthermore, the structural elements can comprise at least a first group of structural elements having a first extension size and a second group of structural elements having a second extension size, and the first extension size is different from the second extension size. Particularly preferably, in this case, the light generated by the light-emitting semiconductor component in operation can have at least a first spectral component and a second spectral component different therefrom, wherein the extension size of the structural elements of the first group is matched to the first spectral component and the extension size of the structural elements of the second group is matched to the second spectral component. Additionally or alternatively, the two groups of structural elements can also affect light of a single emitted wavelength differently.

Preferably, the plurality of structural elements can be arranged in a two-dimensional or three-dimensional matrix in a surrounding material, which can be solid, liquid or gas. Particularly preferably, at least in a resting state of the adaptive optical element, it can be a regular matrix, i.e., a regular arrangement along a two- or three-dimensional grid. Surrounding material refers to a material that surrounds the structural elements, for example on more than one side. For example, the structural elements can have a top side and an opposite bottom side with side surfaces connecting the top side and the bottom side. For example, the surrounding material can be adjacent to at least the top surface and the side surfaces. With the bottom side, the structural elements can be arranged on a supporting element, for example.

According to a further embodiment, the adaptive optical element is intended and configured to influence and control a spatial arrangement and/or an electrical property of the structural elements. For example, a distance between at least some of the structural elements can be influenced and changed in the adaptive optical element. Alternatively or additionally, for example, a density of free charge carriers in the structural elements can be influenced and changed. Furthermore, it can be possible to influence and change the refractive index of a material surrounding the structural elements.

Structural elements in a material surrounding the structural elements with extension sizes of the structural elements in the range of the wavelength of a light transmitting through the structural elements and the surrounding material can, for example, influence the effective refractive index of the transmitted adaptive optical element. Such structural elements can also be referred to as so-called meta-structures or meta-atoms. For example, by changing the spatial arrangement and/or density of free charge carriers, the optical properties of the effect produced by the structural elements can be influenced and changed. In particular, an optical effect of the adaptive optical element on transmitted light can be dynamically changed by a change in the structural elements or the material surrounding them and/or by a mechanical deformation of the adaptive optical element and thus by a change in the arrangement of the structural elements. In particular, for example, a dynamically changeable lens effect can be achieved.

Particularly preferably, the structural elements have a material with the highest possible refractive index, in particular a higher refractive index than a material surrounding the structural elements. Unless otherwise stated, the parameter “refractive index” always refers to the light generated by the light-emitting semiconductor component.

For example, the structural elements have or are made of one or more of the following materials: Si, Ge, TiO₂, ZrO₂, ZnO, ITO, InP, GaAs, InGaAs, metal. Suitable metals include, for example, one or more selected from Au, Ag, Pt, Pd. The material surrounding the structural elements preferably has a refractive index as low as possible and can, for example, comprise a gas such as air or a plastic material. For example, the plastic material can comprise or be a polymer such as a fluoropolymer. In particular, the polymer can be a viscous, elastic or viscoelastic polymer. Furthermore, a liquid crystal material is also possible.

According to a further embodiment, the adaptive optical element comprises a dielectric elastomer actuator. In this case, the adaptive optical element preferably comprises an elastic or viscoelastic polymer arranged at or between electrodes. By applying an electrical voltage to the electrodes, a deformation of the polymer can be achieved, for example via electrostatic attraction or repulsion of the electrodes, which can be dynamically controllable. The structural elements are preferably arranged in or on the dielectric elastomer actuator and thus preferably in or on the polymer. By deforming the polymer, the spatial arrangement of the structural elements can be influenced so that at least local changes in the effective refractive index can be affected.

According to a further embodiment, the adaptive optical element has a liquid crystal layer in which the structural elements are arranged. In this case, the adaptive optical element preferably comprises a liquid crystal material arranged at or between electrodes. By applying an electrical voltage to the electrodes, for example, a changed refractive index of the liquid crystal material can be achieved. Furthermore, a deformation can also be achieved at the same time, for example, so that the adaptive optical element can also be designed as an actuator at the same time as described above.

According to a further embodiment, the adaptive optical element has a dielectric layer between electrodes. In this case, the adaptive optical element preferably comprises a dielectric polymer which is arranged at or between electrodes and in which the structural elements are embedded. Via the electrodes, a density of free charge carriers in the structural elements can be adjusted, whereby the refractive index of the structural elements can be influenced. Furthermore, a deformation can also be achieved simultaneously, for example, so that the adaptive optical element can also be designed as an actuator at the same time as described above.

According to a further embodiment, the adaptive optical element comprises elastic electrodes. These can be, for example, a network with or formed of carbon nanotubes such as single-wall carbon nanotubes (SWCNTs), graphene flakes, or metal nanowires, for example with or formed of silver. Furthermore, it is also possible that the electrodes comprise a transparent electrically conductive material such as a transparent conductive oxide (TCO), for example when an elastic property of the electrodes is not necessary.

The electrodes of the adaptive optical element can be deposited on or embedded in a previously described material such as a polymer or a liquid crystal material, both in the case of elastic electrodes and in the case of inelastic electrodes. Furthermore, the electrodes can preferably be transparent to the light generated by the light-emitting semiconductor component. For example, the electrodes can be formed with a large surface area, structured in sections, and/or integrally structured, for example, in a ring shape.

For the electrical connection of the light-emitting semiconductor component and the adaptive optical element, electrical contact elements can be provided in the housing body as described above. For example, the light-emitting semiconductor component can be electrically connected via at least one electrical contact element of the housing body. Furthermore, the adaptive optical element can be electrically connected via at least one electrical contact element of the housing body. For this purpose, the housing body can have conductor tracks in its interior or on a surface, for example on the surface of the cavity, which electrically conductively connect the electrical contact elements to the electrodes of the adaptive optical element. In a particularly simple embodiment, the housing body can have at least three electrical contact elements, wherein the light-emitting semiconductor component is electrically connected via at least a first and a second electrical contact element and the adaptive optical element is electrically connected via at least the second and a third electrical contact element. In this case, the second electrical contact element can, for example, provide a common reference potential for the light-emitting semiconductor component and the adaptive optical element.

Furthermore, at least one electronic component can be arranged in the housing body, i.e. in the cavity of the housing body and/or in the material of the housing body. The electronic component can, for example, have a controller for the light-emitting semiconductor component and/or for the adaptive optical element or at least a part thereof.

According to a further embodiment, the housing body has a transparent cover plate. For example, the cover plate can comprise or be made of a glass, sapphire, or an inelastic plastic such as a hard polymer. Particularly preferably, the cover plate can hermetically seal the cavity of the housing body in which the light-emitting semiconductor component is arranged. Further, the adaptive optical element can be arranged on the cover plate such that the cover plate forms a support for the adaptive optical element. Preferably, the adaptive optical element can be arranged on the cover plate on a side facing the light-emitting semiconductor component.

According to at least one further embodiment, a LIDAR system (LIDAR: “light detection and ranging”) comprises the light-emitting device. Particularly preferably, based on the embodiments and features described above, the light-emitting device can be intended and configured for the LIDAR system to have a variable radiation characteristic during operation, in particular by changing the distribution of the radiation flux, for example at least between a wide radiation angle and a narrow radiation angle.

The light-emitting device described herein can offer the advantage that a customer or user of the light-emitting device can change the radiation profile of the emitted light during operation by the adaptive optical element integrated in the light-emitting device. For example, a distribution of the radiant flux over the half-space angle can be controlled. Thus, for example, in a (flash) LIDAR application, it is possible to switch between a wide beam angle, i.e. a wide “Field Of View” (FOV), for close range (lower irradiance) and a narrow FOV for longer distances (high irradiance). Lateral shifting of the emitted light cone during operation is also possible. Thus, in the light-emitting device described here, moving parts such as mirrors or moveable lens systems are not necessary. At the same time, the adaptive optical element described here makes the device as flat and small as conventional package-based semiconductor light sources. In terms of manufacturing, the light-emitting device can offer the advantage that identical devices can be used and sold for different applications and still meet special customer requirements regarding the radiation profile.

Further advantages, advantageous embodiments and further developments are revealed by the embodiments described below in connection with the figures.

### BRIEF DESCRIPTION OF THE DRAWINGS

FIG. 1 shows a schematic illustration of a light-emitting device according to an embodiment;

FIG. 2 shows a schematic illustration of a light-emitting device according to a further embodiment;

FIGS. 3 to 5 show schematic illustrations of an adaptive optical element of a light-emitting device according to further embodiments;

FIGS. 6A to 6D show schematic illustrations of an adaptive optical element of a light-emitting device according to further embodiments; and

FIG. 7 shows a schematic illustration of a LIDAR system with a light-emitting device according to a further embodiment.

### DETAILED DESCRIPTION OF ILLUSTRATIVE EMBODIMENTS

In the embodiments and figures, identical, similar or identically acting elements are provided in each case with the same reference numerals. The elements illustrated and their size ratios to one another should not be regarded as being to scale, but rather individual elements, such as for example layers, components, devices and regions, can have been made exaggeratedly large to illustrate them better and/or to aid comprehension.

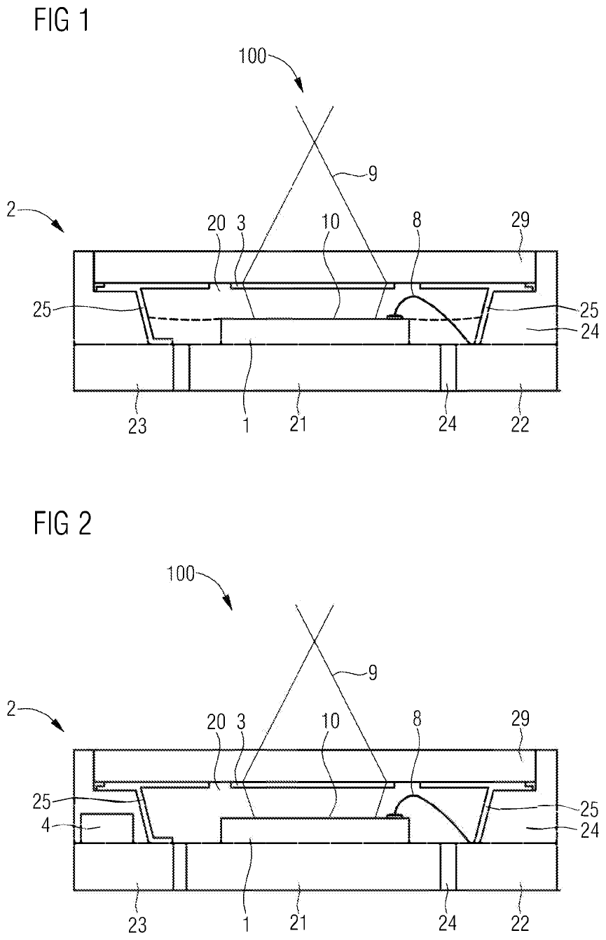

FIG. 1 shows an embodiment of a light-emitting device 100. The light-emitting device 100 is embodied as a surface-mounted device and has a light-emitting semiconductor component 1 in a housing body 2.

The light-emitting semiconductor component 1 can, for example, be a laser diode, an SLED or an LED. In the embodiment shown, the light-emitting semiconductor component 1 is embodied, purely by way of example, as a single semiconductor chip. Alternatively, the light-emitting semiconductor component 1 can comprise a plurality of semiconductor chips. As described in the general part, the semiconductor chip comprises a semiconductor layer sequence based on a suitable semiconductor material with an active region in which light 9 is generated during operation. In the embodiment shown, the light-emitting semiconductor component 1 is a surface emitting device which, in operation, emits light perpendicular to the main extension plane of the semiconductor layers of the semiconductor layer sequence via a light-outcoupling surface 10. For example, the light-emitting semiconductor component 1 can be embodied as an LED chip as indicated in FIG. 1 or also as a VCSEL or as a PCSEL. Furthermore, the light-emitting semiconductor component 1 can also be embodied, for example, as an SLED, as an edge-emitting laser diode or as an HCSEL, which is mounted in the housing body 2 rotated by 90° or which has one or more reflector surfaces integrated into the semiconductor layer sequence, for example by etching, and inclined by 45°. Purely by way of example, the upper side of the light-emitting semiconductor component 1 is electrically contacted via a bonding wire 8, while the lower side opposite the upper side and thus opposite the light-outcoupling surface, the lower side forming the mounting surface, can be electrically contacted directly. Alternatively, the light-emitting semiconductor component 1 can also be electrically contacted via several bonding wires or only via contact areas arranged on the lower side.

Furthermore, the light-emitting semiconductor component 1 can additionally comprise a wavelength conversion material (not shown) that can convert at least a portion of the light 9 generated by the light-emitting semiconductor component 1 in operation into light in a different wavelength range so that mixed color light can be generated, for example. Alternatively or additionally, mixed-color light can also be generated, for example, by several different light-emitting semiconductor chips.

In the shown embodiment, the housing body 2 has a cavity 20 in which the light-emitting semiconductor component 1 is arranged, mounted and electrically connected. For this purpose, the housing body 2 has electrical contact elements 21, 22, 23, which in the shown embodiment are formed by leadframe parts to which a housing body material formed by a plastic material is molded, by means of which also the cavity 20 can be formed. In particular, the housing body 2 can be embodied as a QFN type housing as shown. Alternatively, the housing body 2 can be embodied, for example, as a ceramic-based housing or other package type.

Particularly preferably, the housing body 2 has dimensions that are less than or equal to 5 cm or less than or equal to 2 cm or less than or equal to 1 cm or less than or equal to 0.5 cm or less than or equal to 0.3 cm. In particular, the dimensions can be a length and a width of the mounting surface of the housing body 2 with the contact elements 21, 22, 23. Accordingly, the light-emitting device 100 is embodied as a so-called semiconductor package. In particular, the housing body 2 and thus the light-emitting device 100 are formed as an SMD component which can be soldered with the electrical contact elements 21, 22, 23 on a carrier such as a printed circuit board.

Furthermore, the light-emitting device comprises an adaptive optical element 3 arranged downstream of the light-emitting semiconductor component 1 in the beam path of the light 9 generated by the light-emitting semiconductor component 1 in operation. In particular, the adaptive optical element 3 is arranged in or on the housing body 2 and is thus an integral part of the light-emitting device 100. In the embodiment shown, the housing body 2 has a transparent cover plate 29 which comprises or is made of, for example, a glass, sapphire or an inelastic plastic such as a hard polymer. In particular, the cover plate 29 can seal, especially hermetically seal, the cavity 20 of the housing body 2 in which the light-emitting semiconductor component 1 is arranged. As shown in FIG. 1, the housing body material 24 can, for example, have a bearing surface surrounding the cavity on which the cover plate 29 is arranged. For example, the cover plate 29 can be glued on or, via corresponding soldering surfaces on the cover plate 29 and the housing body material 24, soldered on.

As an alternative to the embodiment shown, the housing body 2 can, for example, be embodied as a carrier plate on which a ring forming a cavity can be arranged around the light-emitting semiconductor component 1. Further, the cover plate 29 can have a thickened portion at the edge thereof for arranging the cover plate 29 on the carrier plate.

In the embodiment shown, the adaptive optical element 3 is arranged on the cover plate 29. Preferably, the adaptive optical element 3 can be arranged on the cover plate 29 on a side facing the light-emitting semiconductor component 1 as shown. This can ensure that the adaptive optical element 3 can be protected by the housing body 2 from damaging influences from the environment. Alternatively, however, an arrangement outside the cavity 20 of the housing body 2 can also be possible, in which case an additional protective layer over the adaptive optical element 3 can be advantageous.

The cavity 20 in the housing body 2, as shown in FIG. 1, is preferably free of a casting material at least in the region of the adaptive optical element 3 and is gas-filled, for example with air or an inert protection gas. The light-emitting semiconductor component 1 can, for example, be casted to the top with a reflective, for example white, material, as indicated by the dashed lines in FIG. 1, in order to promote light radiation upwards towards the adaptive optical element 3.

Thus, in the light-emitting device 100, in which the housing body can be, for example, a QFN or ceramic-based housing body as mentioned previously, the cover plate 29 and the adaptive optical element 3 are provided instead of a conventional lens or multiple lens array. The cover plate 29 can protect both the light-emitting semiconductor component 1 and the adaptive optical element 3 from environmental influences.

The adaptive optical element 3 has electrodes 30, as described in more detail below. For electrical contacting, the housing body 2 has corresponding electrical contact elements 22, 23, as already shown for contacting the light-emitting semiconductor component 1. Furthermore, as shown, conductor paths 25 can be provided on an inner wall of the cavity 20 and/or vias through the housing body material 24 (not shown), for example, to electrically connect the adaptive optical element 3 to the electrical contact elements 22, 23. During the design and assembly of the housing body 2, it must be ensured that at least two contact surfaces for applying the electrical voltage for controlling the adaptive optical element 3 are electrically connected to the housing body 2.

In case the adaptive optical element 3 has exactly two electrodes 30 to be contacted, it can be possible, for example, for the housing body 2 to have at least three electrical contact elements 21, 22, 23 as shown, with the light-emitting semiconductor component 1 being electrically connected via at least a first and a second electrical contact element 21, 22 and the adaptive optical element 3 being electrically connected via at least the second electrical contact element 22 and a third electrical contact element 23. In this case, the second electrical contact element 22 can, for example, provide a common reference potential for the light-emitting semiconductor component 1 and the adaptive optical element 3. Alternatively, the light-emitting semiconductor component 1 and the adaptive optical element 3 can be electrically connected separately, so that the housing body 2 can have at least four electrical contact elements in this case. Depending on the number of electrodes and connections of the light-emitting semiconductor component 1 and the adaptive optical element 3, there can also be more than those electrical contact elements.

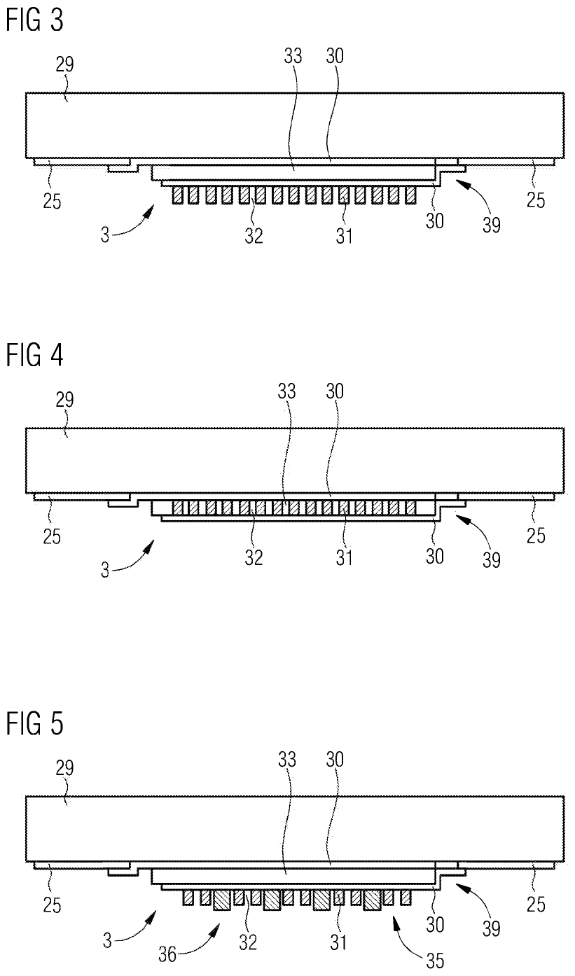

FIG. 2 shows a further embodiment for the light-emitting device 100, which has, compared to embodiment of FIG. 1, at least one electronic component 4 in the housing body 2. As shown, the at least one electronic component 4 can, for example, be embedded in the housing body material 24 of the housing body 2. Alternatively or additionally, the at least one electronic component can also be arranged in the cavity 20 of the housing body 2. The at least one electronic component 4 can, for example, comprise a controller for the light-emitting semiconductor component 1 and/or for the adaptive optical element 2 or at least a part thereof. According to the configuration of the at least one electronic component 4, which can also comprise a plurality of discrete components, the housing body 2 can also comprise a suitable number of electrical contact elements. The electronic component 4 can also include a digital interface connected to the electrical contact elements. Alternatively, an interface for radio control, for example by WLAN or Bluetooth, can be included.

The housing body 2 can thus contain further electronic components in the form of the at least one electronic component 4, such as a capacitor for pulse operation, an integrated circuit (IC) for signal control of the light-emitting semiconductor component 1 and/or for control of the adaptive optical element 3. In particular, a suitable electronic component can also optionally generate the (high) voltage required for control of the adaptive optical element 3 within the housing body 2 from the operating voltage. On the outside of the housing body 2, for example, at least two electrical contact elements can be provided for the electrical supply and at least one further electrical contact element can be provided for the, possibly digital, control of the light-emitting semiconductor component 1 and/or for the control of the adaptive optical element 3.

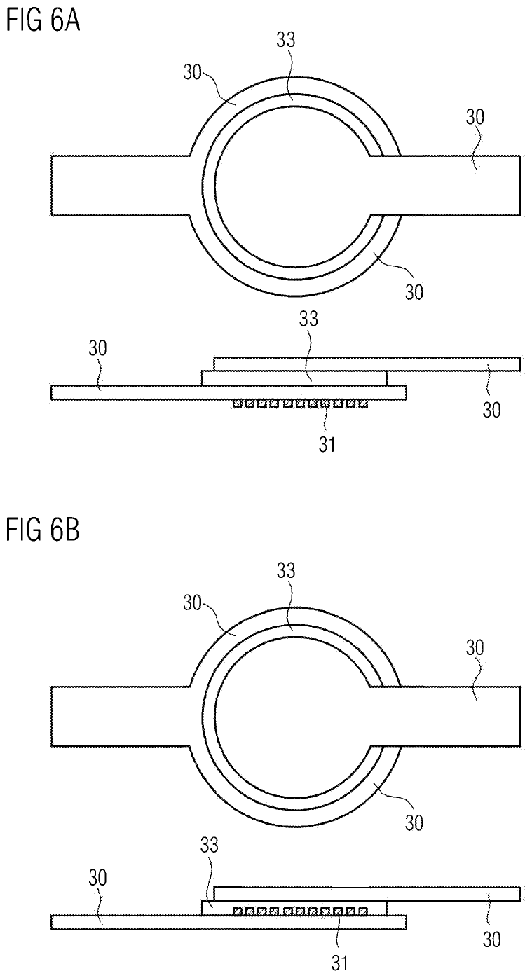

In FIG. 3, the cover plate 29 with the adaptive optical element 3 is shown in an enlarged view.

The adaptive optical element 3 has a plurality of structural elements 31 on or in a supporting element 39. Each of the structural elements 31 has an extension size that is adapted to a wavelength of light generated by the light-emitting semiconductor component. In particular, the structural elements 31 can have an extension size that is smaller than or equal to a wavelength of the light generated by the light-emitting semiconductor component. Accordingly, the adaptive optical element 3 can have a sub-wavelength structure.

As indicated in FIG. 3, the structural elements 31 can preferably be columnar and have a cylindrical shape or a frustoconical shape with a round or a polygonal base.

In preferred embodiments, the adaptive optical element 3 is intended and configured to influence and control a spatial arrangement and/or an electrical property of the structural elements 31. For example, a spacing of at least some or all of the structural elements 31 with respect to each other in the adaptive optical element 3 can be specifically influenced and changed. Alternatively or additionally, for example, a density of free charge carriers in the structural elements 31 can be specifically influenced and changed.

The plurality of structural elements can preferably be arranged in a two-dimensional matrix as shown, or can also be arranged in a three-dimensional matrix in a surrounding material 32, which can be solid, liquid or, as shown in FIG. 3, gaseous. In the latter case, the surrounding material can be, for example, air or an inert gas enclosed in the cavity of the housing body. Particularly preferably, at least in a resting state of the adaptive optical element 3, it can be a regular matrix, i.e. a regular arrangement along a two- or three-dimensional grid.

By the structural elements 31 in the material 32 surrounding the structural elements 31, an effective material, which can also be referred to as a meta-material, can be formed whose effective refractive index can be influenced by the structural elements 31 due to the extension sizes of the structural elements 31 in the range of the wavelength of a light transmitted through the structural elements 31 and the surrounding material 32. For example, by changing the distance between structural elements 31 and/or the density of free charge carriers, the optical properties of the effect caused by the structural elements 31 can be influenced and changed. In particular, an optical effect can be dynamically changed by changing the structural elements 31 or the material 32 surrounding them and/or by mechanically deforming the adaptive optical element 3 and thus changing the arrangement of the structural elements 31. In particular, for example, a dynamically changeable lens effect can be achieved.

The structural elements 31 can be formed, for example, by a lithography and etching process in which a surface structure corresponding to the desired shape and arrangement of the structural elements 31 can be formed in a plate or layer of the material of the structural elements. The surface structure can be detached from the remaining material to form the structural elements. For this purpose, the surface structure and thus the subsequently separated structural elements 31 can be molded, for example, with a plastic material that can form a stabilizing matrix. The plastic material can be removed after the detachment and transfer of the structural elements 31 to another element of the adaptive optical element, or it can remain as surrounding material 32.

The adaptive optical element 3 further comprises an active material 33 by which manipulation and modification of the adaptive optical element 3 can be achieved. For example, the structural elements 31 can be transferred to a dielectric elastomer actuator as a supporting element 39, as shown in the embodiment of FIG. 3. In this case, the adaptive optical element 3 preferably has an elastic or viscoelastic polymer as the active material 33 arranged on or, as indicated in FIG. 3, between electrodes 30. By applying an electrical voltage to the electrodes 30, a deformation of the polymer can be achieved, for example via an electrostatic attraction of the electrodes 30, which can be dynamically controllable. The structural elements 31 are arranged in or, as shown in FIG. 3, on the dielectric elastomer actuator and thus preferably on the active material 33 and/or one of the electrodes 30. By deforming the polymer, the spatial arrangement of the structural elements 31 can be influenced so that at least local changes in the effective refractive index of the adaptive optical element 3 can be affected.

Particularly preferably, the structural elements 31 have a material with a refractive index as high as possible, in particular a higher refractive index than the material 32 surrounding the structural elements 31. For example, the structural elements 31 comprise or are made of one or more of the following materials: Si, Ge, TiO₂, ZrO₂, ZnO, ITO, InP, GaAs, InGaAs, metal. Suitable metals include, for example, one or more selected from Au, Ag, Pt, Pd. The material 32 surrounding the structural elements 31 preferably has as low a refractive index as possible to maximize the effect of scattering, and as shown can be, for example, a gas such as air or an inert gas.

Particularly preferably, the adaptive optical element 3 has elastic electrodes 30. These can be formed, for example, by a network with or of carbon nanotubes, such as SWCNTs, with or of graphene flakes, and/or with or of metal nanowires, for example with or of silver. Furthermore, it is also possible that the electrodes 30 comprise a transparent electrically conductive material, such as a TCO, for example when an elastic property of the electrodes is not necessary or when TCO (nano) particles are embedded in an elastic matrix material. Particularly preferably, the electrodes as well as the polymer between the electrodes are as transparent as possible, or at least partially transparent, to the light generated by the light-emitting semiconductor component during operation.

The electrodes 30 of the adaptive optical element 3 can be deposited on or embedded in a previously described material such as a polymer, both in the case of elastic electrodes and in the case of inelastic electrodes. Further, the electrodes 30 can preferably be transparent to the light generated by the light-emitting semiconductor component as described in advance. The electrodes 30 can be formed over a large area, as shown in FIG. 3. Further, one or more electrodes 30 can also be formed into sections structured and/or integrally structured, for example annular, as explained further below.

As an alternative to the embodiment shown in FIG. 3, the material 32 surrounding the structural elements 31 can, for example, comprise or be a plastic material. The plastic material can, for example, comprise or be a polymer such as a fluoropolymer. In particular, the polymer in this case can be the active material 33, such as the elastic or viscoelastic polymer of the dielectric elastomer actuator, as shown in FIG. 4. In this case, the structural elements 31 are thus arranged between the electrodes 30 and thus within the active material 33 and thus also within the supporting element 39. The layer thickness of the active material 33 can be greater than the extension size of the structural elements 32 in the direction perpendicular to the layer of the active material 33.

Alternatively, for example, instead of the elastic or viscoelastic material, a liquid crystal material is also possible as the active material 33 between the electrodes 30. In this case, the adaptive optical element has a liquid crystal layer in which the structural elements are arranged. In other words, the adaptive optical element has a liquid crystal material arranged on or between electrodes. By applying an electric voltage to the electrodes 30, for example, a refractive index of the liquid crystal material can be achieved. Furthermore, a deformation can also be achieved at the same time, for example, so that the adaptive optical element 3 can also be embodied as an actuator at the same time as described above.

Furthermore, the adaptive optical element 3 can have a dielectric layer as active material 33 between the electrodes 30, in which the structural elements 31 are embedded, whereby a density of free charge carriers in the structural elements 31 can be adjusted via the electrodes 30, whereby the refractive index of the structural elements 31 can be influenced. Furthermore, for example, a deformation can also be achieved simultaneously, so that the adaptive optical element 3 can also be embodied as an actuator at the same time as described above.

Particularly advantageously, the emission of the light-emitting semiconductor component is monochromatic, since the dimensions d of the structural elements 31 must be adapted to the wavelength of the light, with d˜ 1/n, where n is the refractive index of the structural elements 31. However, by using different sized structural elements 31, multiple wavelengths can be affected, for example in the case of white light, such as that needed for headlight applications. As shown in FIG. 5, it can thus be that the structural elements 31 comprise at least a first group 35 of structural elements 31 having a first extension size and a second group 36 of structural elements 31 having a second extension size, and the first extension size is different from the second extension size. Particularly preferably, in this case, the light generated by the light-emitting semiconductor component in operation can have at least a first spectral component and a second spectral component different therefrom, and the extension size of the structural elements 31 of the first group 35 can be matched to the first spectral component and the extension size of the structural elements 31 of the second group 36 can be matched to the second spectral component. Furthermore, there can be more than two groups with different sized structural elements 31.

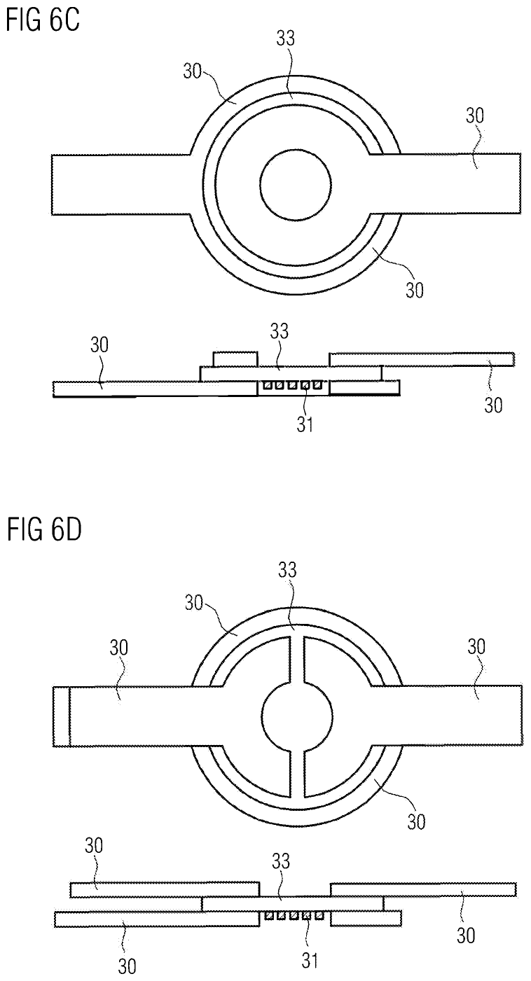

FIGS. 6A and 6B show a sectional view and a top view of adaptive optical elements with electrodes formed over a large area. The structural elements can be arranged outside (FIG. 6A) or inside (FIG. 6B) of the two electrodes 30 and thus outside or inside of the active material 33, as described above. In the case of a dielectric elastomer actuator, when an electrical voltage is applied, the electrodes 30 approach each other, compressing the polymer volume formed by the active material 33 in the direction perpendicular to the electrodes 30 and simultaneously stretching it in the lateral direction. This gives the structural elements 31 an extended lateral distance from each other, which can change the scattering effect and thus the radiation profile.

To reduce the absorption of the emitted light by the electrodes 30, they can also be arranged in a ring around the emission area, for example, as shown in FIG. 6C. By applying a voltage, in the case of a dielectric elastomer actuator, the ring then compresses its center with the structural elements 31.

Furthermore, at least one of the electrodes can be structured into several areas that can be controlled independently of one another, as shown in FIG. 6D with electrodes that are structured purely exemplary as partial rings. Alternatively, for example, a large-area electrode can also be structured into several regions that can be controlled independently of one another.

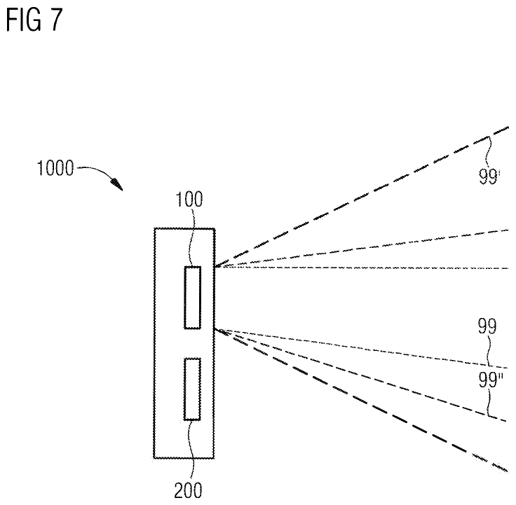

FIG. 7 shows a LIDAR system 1000 with a previously described light-emitting device 100 as a transmitting unit. The light-emitting device 100 is intended and configured for the LIDAR system 1000 to have a variable radiation pattern 99, 99′, 99″ during operation, as indicated by different radiation cones in FIG. 7. In particular, the adaptive optical element of the light-emitting device 100 can be used to change the distribution of the radiation flux. For example, it is possible to switch discretely or continuously between a radiation pattern 99 having a narrow radiation angle, i.e., a narrow FOV, such as for the far range, and a radiation pattern 99′ having a wide radiation angle, i.e., a wide FOV, such as for the near range. A lateral shift of the radiated light cone during operation is also possible, as indicated in connection with the radiation characteristic 99″.

In operation, the light-emitting device 100 emits, for example, at least one transmitter signal, which can be, for example, a light pulse emitted in the form of a single pulse having a specific pulse frequency. Furthermore, instead of a single pulse, the transmitter signal can, for example, also comprise a pulse train, i.e., a plurality of pulses, and/or an amplitude-modulated pulse or an amplitude- and/or phase-modulated continuous light beam.

The LIDAR system 1000 can further comprise a detector unit 200, for example in the form of a photodiode or a photodiode array, which is intended and configured to receive a return signal comprising at least a portion of the transmitter signal reflected back from an external object. The return signal can differ from the transmitter signal due to interaction of the transmitter signal with an object, for example with respect to the time course, a spectral composition, an amplitude and/or a phase. For example, the return signal can correspond to a transmitter signal that is attenuated and/or at least partially frequency-shifted and/or phase-shifted with respect to at least some spectral components.

The features and embodiments described in connection with the figures can be combined with each other according to further embodiments, even if not all combinations are explicitly described. Furthermore, the embodiments described in connection with the figures can alternatively or additionally have further features according to the description in the general part.

The invention is not limited by the description based on the embodiments to these embodiments. Rather, the invention includes any new feature and any combination of features, which includes in particular any combination of features in the patent claims, even if this feature or this combination itself is not explicitly explained in the patent claims or embodiments.

1.-20. (canceled)

21. A light-emitting device comprising:
a housing body;
a light-emitting semiconductor component in the housing body, the light-emitting component configured to emit light; and
an adaptive optical element in and/or on the housing body arranged downstream of the light-emitting semiconductor component in an optical path of the light,
wherein the light-emitting device is a semiconductor package.

22. The light-emitting device according to claim 21, wherein the light-emitting device is a surface mountable device.

23. The light-emitting device according to claim 21, wherein the housing body comprises a plastic housing or a ceramic housing.

24. The light-emitting device according to claim 21, wherein the adaptive optical element comprises a plurality of structural elements, and wherein the structural elements have an extension size adapted to a wavelength of the light.

25. The light-emitting device according to claim 24, wherein the extension size is less than or equal to a wavelength of light emittable by the semiconductor light-emitting component.

26. The light-emitting device according to claim 24, wherein the structural elements comprise at least a first group of structural elements having a first extension size and a second group of structural elements having a second extension size, the first extension size being different from the second extension size.

27. The light-emitting device according to claim 26, wherein the light generated by the light-emitting semiconductor component has at least a first spectral component and a second spectral component different therefrom, and wherein the extension size of the structural elements of the first group are matched to the first spectral component and the extension size of the structural elements of the second group are matched to the second spectral component.

28. The light-emitting device according to claim 24, wherein the adaptive optical element comprises a dielectric elastomer actuator in or on which the structural elements are arranged.

29. The light-emitting device according to claim 24, wherein the adaptive optical element comprises a liquid crystal layer in which the structural elements are arranged.

30. The light-emitting device according to claim 24, wherein the adaptive optical element comprises a dielectric layer between electrodes, and wherein a density of free charge carriers in the structural elements are adjustable via the electrodes.

31. The light-emitting device according to claim 21, wherein the adaptive optical element comprises elastic electrodes.

32. The light-emitting device according to claim 21, wherein the light-emitting semiconductor component is electrically connected via at least one electrical contact element of the housing body.

33. The light-emitting device according to claim 21, wherein the adaptive optical element is electrically connected via at least one electrical contact element of the housing body.

34. The light-emitting device according to claim 21, wherein the housing body comprises at least three electrical contact elements, wherein the light-emitting semiconductor component is electrically connected via at least a first electrical contact element and a second electrical contact element, and wherein the adaptive optical element is electrically connected via at least the second electrical contact element and a third electrical contact element.

35. The light-emitting device according to claim 21, wherein the housing body comprises a transparent cover plate.

36. The light-emitting device according to claim 35, wherein the cover plate hermetically seals a cavity of the housing body in which the light-emitting semiconductor component is arranged.

37. The light-emitting device according to claim 35, wherein the adaptive optical element is arranged on the cover plate on a side facing the light-emitting semiconductor component.

38. The light-emitting device according to claim 21, wherein at least one electronic component is arranged in the housing body, which is configured to drive the light-emitting semiconductor component and/or the adaptive optical element.

39. A LIDAR system comprising:
at least one light-emitting device according to claim 21,
wherein the LIDAR system is configured to emit light with a radiation pattern that is variable.

40. A Light-emitting device comprising:
a housing body;
a light-emitting semiconductor component in the housing body, the light-emitting semiconductor component configured to emit light; and
an adaptive optical element in and/or on the housing body arranged downstream of the light-emitting semiconductor component in an optical path of the light,
wherein the light-emitting device is a semiconductor package,
wherein the adaptive optical element comprises a plurality of structural elements,
wherein the structural elements have an extension size adapted to a wavelength of the light,
wherein the adaptive optical element comprises a dielectric elastomer actuator in or on which the structural elements are arranged.
